(19) United States
(12) Patent Application Publication
(10) Pub. No.: US 2021/0005228 A1
(43) Pub. Date: Jan. 7, 2021

(54) EFFICIENT THERMALLY-ASSISTED MEMORY DEVICE

(71) Applicant: Vathys, Inc., Portland, OR (US)

(72) Inventor: Tapabrata Ghosh, Portland, OR (US)

(21) Appl. No.: 16/459,563

(22) Filed: Jul. 1, 2019

(51) Int. Cl. G11C 5/14; G11C 11/22; G11C 11/4074; G11C 11/4096; G11C 11/408; G11C 11/418; G11C 11/419

(52) U.S. Cl. CPC G11C 5/147; G11C 11/223; G11C 11/2259; G11C 11/2273; G11C 11/2275; G11C 11/419; G11C 11/4074; G11C 11/4096; G11C 11/408; G11C 11/418; G11C 11/2297

(57) ABSTRACT

Disclosed are systems and methods for thermally-assisted memory devices, for example SRAM, DRAM or FRAM memory devices. In some embodiments, temperature of one or more memory cells can be increased, thereby reducing a voltage threshold of the transistors therein. Temporary lowering of transistor voltage threshold can increase the performance of the memory device during dynamic operations. The transistors can revert back to a high voltage threshold when the memory device is static or is in standby mode, thereby reducing subthreshold leakage and improving the power consumption of the memory device.

### BACKGROUND

### Field of the Invention

This invention relates generally to the field of computer hardware and more particularly to efficient memory devices.

### Description of the Related Art

Memory technology continues to be both a key enabler and a barrier to rapid progress in all aspects of modern technology. Memory technology has historically lagged behind improvements in central processing unit (CPU) technology and other computing components, in terms of speed, size, and power consumption. This has been a limiting factor on the performance of computing systems. The improvement of memory technology is thus an important aspect of the advancement of computer-related technology. Moore's Law, circuit scaling, wire scaling, integrated circuits, and microprocessors have intersected with trends in workloads such as the application of machine learning, artificial intelligence (AI), and the internet of things (TOT) to place even more importance on the need for improvement of memory technology.

An ideal memory technology would be nonvolatile (maintain its current state with no connection to power), small, scalable, and exhibit low operating voltages, high switching speed, low power consumption, long retention time, high endurance, and be cost effective to manufacture. Unfortunately, these characteristics can be difficult to achieve in one device technology, and to date, there does not exist a single solution that optimally combines all the desired properties.

Current memory technologies in wide-spread use include dynamic random-access-memory (DRAM) and static random-access-memory (SRAM). Recently, alternative memory technologies have been proposed. These include carbon nanotube (CNT) random-access-memory, ferroelectric random-access-memory (FRAM), phase-change memory, filamentary resistive random-access-memory, and others. These technologies promise to solve existing limitations in memory devices. However, so far, they can be difficult or expensive to manufacture, have problems with reliability in the field, or have other problems such as low storage density or poor cell endurance. Therefore, devices and techniques that can make existing memory technology more efficient and reliable are needed.

### SUMMARY

In one aspect of the invention, a system is disclosed. The system includes: a memory array comprising a plurality of memory cells, wherein memory cells comprise a plurality of transistors, each transistor having a voltage threshold; a memory address module comprising a pipeline of memory addresses marked for access during an access period; a heating element layer in close proximity to or adjacent to the memory array and comprising heating elements; and a controller, in communication with the memory address module, and configured to lower one or more transistor voltage thresholds by: determining memory cells associated with memory addresses marked for access; and activating one or more heating elements corresponding to the determined memory cells for a period of time comprising the access period.

In one embodiment, the controller is further configured to send a pause signal to the memory array, pausing the access for a predetermined period of time.

In some embodiments, the controller includes a timing module configured to generate and update a timing schedule of activating the one or more heating elements in relation to timing of access period.

In another embodiment, the heating elements comprise circuit elements having adjustable processing rates and activating the one or more heating elements comprise increasing the processing rates.

In one embodiment, access comprises writing into the memory cells, reading from the memory cells, or both.

In some embodiments, the plurality of memory cells comprise SRAM cells, DRAM cells, or FRAM cells.

In one embodiment, the transistors comprise high-voltage transistors or UHVT transistors.

In another embodiment, the heating elements comprise resistive microheaters.

In one embodiment, the memory cells comprise four or more transistors.

In some embodiments, the memory cells comprise 1T1C cells, 2T1C cells, 2T2C cells, 1T2C cells, gain cells, or a combination thereof.

In another aspect of the invention, a method is disclosed. The method includes: receiving memory addresses marked for memory access and an access period associated with the memory access; determining memory cells within a memory array and associated with the memory addresses marked for access; and lowering transistor voltage thresholds of one or more transistors of the determined memory cells for a period of time comprising the access period.

In one embodiment, lowering transistor voltage thresholds comprises activating one or more heating elements corresponding to the determined memory cells for a period of time comprising the access period.

In another embodiment, the heating elements comprise circuit elements having adjustable processing rates and activating the one or more heating elements comprise increasing the processing rates.

In some embodiments, the heating elements comprise resistive microheaters.

In another embodiment, access comprises writing into the memory cells, reading from the memory cells, or both.

In one embodiment, the memory cells comprise SRAM cells, DRAM cells, or FRAM cells.

In some embodiments, the method further includes pausing the access for a predetermined period of time.

In one embodiment, the memory cells comprise four or more transistors.

In another embodiment, the memory cells comprise 1T1C cells, 2T1C cells, 2T2C cells, 1T2C cells, gain cells, or a combination thereof.

In another aspect of the invention a method is disclosed. The method includes: activating one or more heating elements, each heating element corresponding to one or more memory cells of a memory array; determining memory addresses associated with the one or more memory cells; receiving memory access requests from a processor, wherein the access request comprises request for writing input data into the memory array; writing the input data into the one or more memory cells; and deactivating the one or more heating elements.

### BRIEF DESCRIPTION OF THE DRAWINGS

These drawings and the associated description herein are provided to illustrate specific embodiments of the invention and are not intended to be limiting.

FIG. 1 illustrates a diagram of a memory cell, which uses a six-transistor SRAM architecture.

FIG. 2 illustrates a diagram of a memory cell, which uses DRAM architecture.

FIG. 3 illustrates a diagram of a memory device, thermally-assisted according to an embodiment.

FIG. 4 illustrates a diagram of a heating element layer and a controller according to an embodiment.

FIG. 5 illustrates a method of operation of a thermally-assisted memory device according to an embodiment.

FIG. 6 illustrates a diagram of a memory cell, using an example FRAM cell topology.

### DETAILED DESCRIPTION

The following detailed description of certain embodiments presents various descriptions of specific embodiments of the invention. However, the invention can be embodied in a multitude of different ways as defined and covered by the claims. In this description, reference is made to the drawings where like reference numerals may indicate identical or functionally similar elements.

Unless defined otherwise, all terms used herein have the same meaning as are commonly understood by one of skill in the art to which this invention belongs. All patents, patent applications and publications referred to throughout the disclosure herein are incorporated by reference in their entirety. In the event that there is a plurality of definitions for a term herein, those in this section prevail. When the terms “one”, “a” or “an” are used in the disclosure, they mean “at least one” or “one or more”, unless otherwise indicated.

### Definitions

The term “subthreshold leakage” can refer to the current between two terminals of a transistor, for example, between the source and drain terminals of a metal-oxide-semiconductor field-effect transistor (MOSFET), when the transistor is in subthreshold region, or weak-inversion region (gate-to-source voltage below the threshold voltage for a MOSFET).

Today's technology demands a massive amount of memory and CPU processing power. The Internet and AI applications alone are placing a burden on current CPU and memory technology. As the IOT connects billions of devices across the world, this trend will multiply. These technologies require memory and memory technology can be a limiting factor on the rapid expansion of these technologies. This can be observed by comparing CPU processing and transfer rates to those achievable by state-of-the-art memory technologies. Memory technologies have not followed Moore's Law and thus have lagged behind CPU advancements. For instance, according to some studies, between the years 1980 and 2000, CPU performance grew at approximately 60% per year while DRAM speeds improved at less than 10% per year over the same period (Carvalho, Carlos; “The Gap between Processor and Memory Speeds”; Proceedings of the International Conference on Computer Architecture, 2002, Braga, Portugal 2002). This trend has continued in recent years even though CPU speed improvements have slowed as we reach the limits of Moore's Law. In addition to speed, size, and power, other properties that are desirable for memory technology have not been fully realized in a single memory technology. These include non-volatility, scalability, long retention time, high endurance, and low manufacturing costs.

A recently developed memory structure, magnetoresistive random-access memory (MRAM), provides several technical advantages that make it an attractive potential to replace current memory standards. Some attractive attributes of MRAMs are their non-volatility, fast read and write speeds, read and write endurance, their potential to scale to small dimensions, and their relatively low power consumption. However, MRAMs continue to suffer a number of disadvantages. For example, MRAMs can be unstable at high frequencies and have limited performance and unstable data retention at high temperatures. Compared to traditional DRAM and SRAM technology, MRAMs currently have a higher power consumption, in part due to technical difficulties in switching MRAM cells during memory operations.

Existing solutions to address technical challenges of MRAM technology include spin-transfer torque (STT) MRAM, spin orbit torque (SOT) MRAM and other techniques. However, most MRAM proposals demand cell architectures and materials that are currently unavailable. As a result, current MRAM or other proposed alternative memory technology can be slower and consume more power than existing memory technologies, such as DRAM and SRAM. Consequently, DRAM and SRAM continue to be the memory architectures of choice for the foreseeable future. Methods and devices that increase DRAM and SRAM performance can also improve the performance of many devices.

SRAM and DRAM are volatile memories and maintain their state when they are provided with power. As a result, SRAM and DRAM can have subthreshold leakage current. For devices incorporating large SRAM or DRAM arrays, subthreshold leakage can be a substantial portion of these devices' power consumption profile. In addition, DRAM and SRAM can be typically slower than the logic circuits which use them as memory devices. It is desirable to increase the speeds of memory devices to bring their performance closer to the performance of their associated logic or processor circuits. DRAM and SRAM can be operated faster and with higher performance if read and write threshold voltages of some transistors in their memory cells are lowered. Two example techniques to lower read/write threshold in a memory cell of an SRAM or DRAM array include choosing low voltage threshold, or ultra-low voltage threshold (ULVT) memory cell transistors (bit cell transistors) or by body-biasing techniques that lower voltage threshold of transistors in a memory cell. However, memory devices that permanently use body-biasing techniques or choose low voltage threshold transistors can suffer from high subthreshold leakage and poor power performance due to increased leakage current in memory cell transistors when the devices are in standby or hold charge mode.

High or ultra-high voltage threshold (UHVT) transistors or body-biasing techniques can be used to curtail subthreshold leakage and improve the power performance of a memory device. These techniques result in high read/write voltages, low speed read/write performance, reduced ability for voltage scaling and high dynamic power consumption. Additionally, dynamic body-biasing techniques have to contend with charging and discharging of large substrate capacitances and charging and discharging large SRAM and DRAM bit cells to accommodate for both n-type and p-type substrate biasing. Consequently, there exists a design trade-off, between memory cells transistor voltage threshold choice and the memory device characteristics and performance metrics. Low transistor voltage thresholds are desirable during the dynamic phase of a memory device's operations (e.g., read or write operations), while high transistor voltage threshold is desirable during static operations (e.g., during standby and hold charge mode).

Temperature Dependency of Transistor Voltage Threshold

Memory devices use transistors to carry out the memory device operations. These transistors can include negative channel metal oxide (NMOS) or positive channel metal oxide (PMOS) transistors. NMOS and PMOS transistors can be modeled as switches. For voltages greater in magnitude than a voltage threshold, the transistors turn on and act as closed switches conducting electricity. For voltages in magnitude below the voltage threshold, the transistors act as open switches and substantially block the flow of current through them. The value of voltage threshold for a transistor can depend on many factors such as substrate bias, surface potential, oxide thickness, doping concentration, and other factors. Transistor voltage threshold is also dependent upon temperature. Although transistors have different regions of operation, generally, an increase in temperature can lower the turn-on voltage threshold of a transistor, consequently, the transistor can be turned on with a lower amount of power compared to similar transistors in cooler temperatures.

SRAM Memory Cell

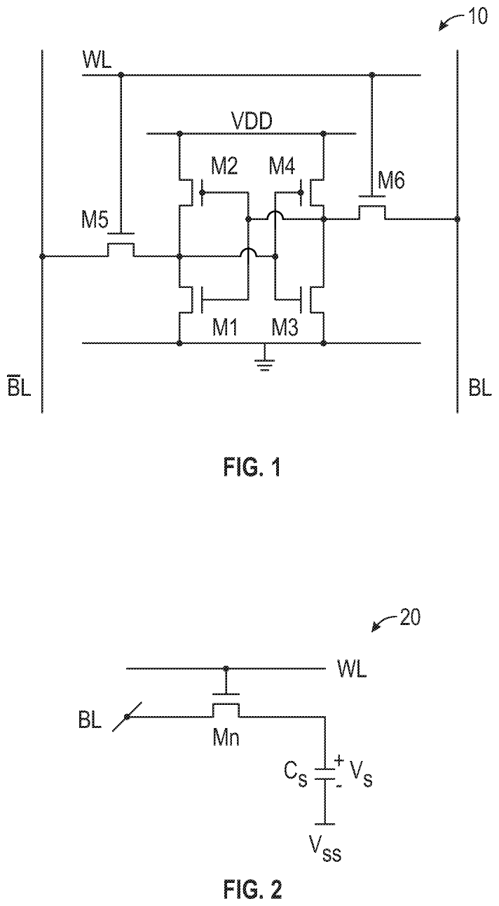

Memory devices can be built using bit cells or memory cells arranged in memory arrays. The bit cells can be written to or read from using various circuitry such as, buffers, decoders, column or row drivers, sense amplifiers, and other control circuitry. An SRAM bit cell can include a variety of configurations and layouts, such as four, six, or more transistors per SRAM cell. FIG. 1 illustrates a diagram of a memory cell 10, which uses a six-transistor SRAM architecture. The memory cell 10 can include two cross-coupled inverters M1-M4 and two access transistors M5 and M6. The cross-coupled inventors M1-M4 are used for storing a binary bit. Read and write operations to and from the cross-coupled inverters M1-M4 are performed via access transistors M5 and M6, word line WL and bit lines BL and B̅L̅.

Read/write operations to and from the memory cell 10 can be made more efficient (faster with less power consumption) if lower voltage-threshold transistors are used to implement the access transistors M5 and M6. However, using low voltage threshold access transistors M5 and M6 can increase subthreshold leakage in those transistors and reduce the efficiency of a memory device incorporating the memory cell 10. The described methods and devices temporarily lower the transistor voltage threshold of the access transistors M5 and M6, by temporarily raising their temperature during read and/or write operations or for a predetermined period of time encompassing the read and/or write operations. When the memory cell 10 is not being used for read/write operations, the voltage threshold of the access transistors M5 and M6 can revert back to a high voltage threshold by lowering their temperature or allowing their temperature to lower by removing a previously applied heat source, thereby reducing subthreshold leakage in those transistors. While a six-transistor SRAM cell is shown for the memory cell 10, the disclosed embodiments can also improve the efficiency of SRAM cells of as few as four-transistor SRAM cells, or SRAM cells of more than six transistors per cell.

DRAM Memory Cell

FIG. 2 illustrates a diagram of a memory cell 20, which uses DRAM architecture. The operations of the memory cell 20 can be improved with the disclosed technology. The memory cell 20 can include a storage capacitor Cs whose state of charge can correspond to a stored binary bit. Read and write operations in memory cell 20 are performed via access transistor Mn, word line WL and bit line BL. A supply voltage Vss helps the storage capacitor Cs maintain its state of charge.

Read/write operations to and from the memory cell 20 can be made more efficient (faster with less power consumption) if access transistor Mn has a lower transistor voltage threshold. However, using a low voltage threshold access transistor Mn can increase subthreshold leakage in that transistor and reduce the efficiency of a memory device incorporating the memory cell 20. The described methods and devices temporarily lower the transistor voltage threshold of the access transistors Mn by temporarily raising its temperature during read and/or write operations or for a predetermined period of time encompassing the read and/or write operations. When the memory cell 20 is not being used for read/write operations, the voltage threshold of the access transistor Mn can revert back to a high voltage threshold by lowering its temperature or allowing its temperature to lower by removing a previously applied heat source, thereby reducing subthreshold leakage in the access transistor Mn. The memory cell 20 can include a variety of DRAM cell topologies, such as one-transistor-one-capacitor (1T1C) cells, two-transistors-one-capacitor (2T1C) cells, two-transistors-two-capacitors (2T2C) cells, one transistor-two-capacitors (1T2C) cells, gain cells, or other topologies.

An Improved Thermally-Assisted Memory Device

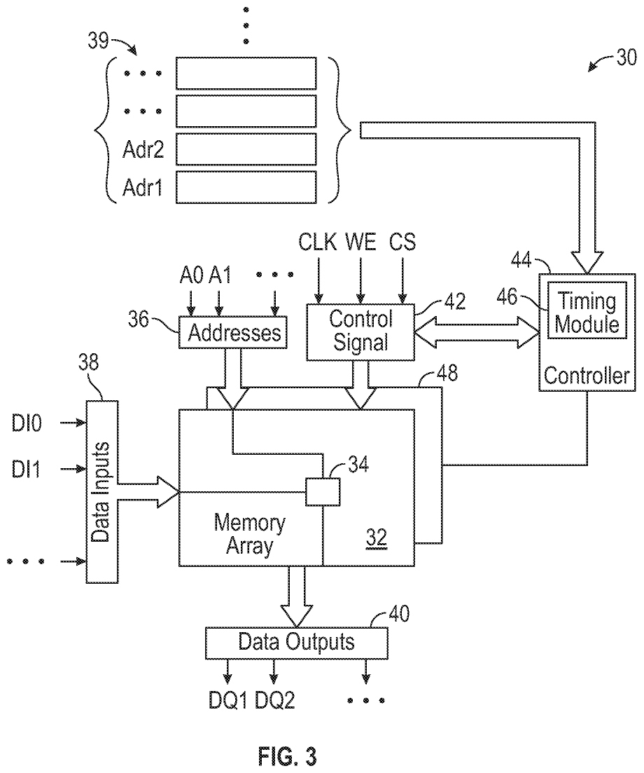

FIG. 3 illustrates a diagram of a memory device 30, which is thermally-assisted according to an embodiment. The memory device 30 can include a memory array 32 with a plurality of memory cells 34, similar to memory cells 10 or memory cells 20, as described in relation to FIGS. 1 and 2. Memory cells 34 can be addressed by an address module 36. A variety of column and row addressing techniques known in the art can be used to access the memory cell 34. A row driver 38 can be used to receive data inputs, DI0, DI1, etc. (from a processor, a hard drive memory, a cache memory, a buffer memory, or other intermediary) and connect those inputs to memory cells 34 indicated by address module 36. One or more differential amplifiers 40 can be used to read data outputs DQ1, DQ2, etc. from the memory array 32 and output those to a computing component which requested the data (e.g., a processor). The details of addressing, read, write and other memory operations can vary depending on the implementation and a variety of techniques can be used.

Control signals 42 can control or assist in the operations of the memory device 30. Control signals 42 can depend on a chosen implementation and can vary based on the design of the memory device 30 and whether or not SRAM, DRAM or other memory technology is used. Example control signals 42 can include, one or more clock signals (CLK), one or more write-enable (WE) signals (e.g., when WE is ON, a memory cell 34 or a plurality of memory cells 34 can be written to), one or more chip-select (CS) signals (e.g., when chip-select is ON, the memory device 30 cannot be written to or writing operations are paused), masking signals (when ON, one or more memory cells 34 are masked from reading or writing operations and remain unaffected), and other control signals as persons of ordinary skill in the art may employ to carry out the operations of the memory device 30.

The memory device 30 can include a controller 44 connected to a heating element layer 48, in close proximity to or adjacent to the memory array 32. The heating element layer 48 can include an array of microheaters, where one or more microheaters in heating element layer 48 correspond to one or more memory cells 34 in the memory array 32. When a microheater in the heating element layer 48 corresponds to one or more memory cells 34, the heat generated by that microheater can reach and raise the temperature of its corresponding memory cell 34. In some embodiments, this can mean the microheater is adjacent to or in thermal close proximity of the memory cell 34. “Close proximity” is dependent on the sizes, dimensions and types of components used to manufacture the memory device 30. In some embodiments, when a resistor of size 1 micrometer (um) is used, a distance of “thermal close proximity” can be a distance between 100 to 500 nanometers (nm). In one embodiment, the heating element layer 48 is in close thermal proximity to the memory array 32, when the heating element layer 48 is within 1 to 100 um of the memory array in the vertical direction. Alternatively, the distances of thermal “close proximity” in the disclosed embodiments can be determined empirically.

The controller 44 can scan a memory pipeline feed containing upcoming memory addresses Adr1, Adr2, etc., marked for read/write operations and determine their physical locations within the memory array 32. Controller 44 can further query a table containing a mapping of physical memory locations on memory array 32 and one or more corresponding microheaters in or on the heating element layer 48. The controller 44 can turn on corresponding microheaters in the heating element layer 48 a time period before the read/write operations are to be executed for an upcoming read/write operation Adr1, Adr2, etc.

The controller 44 can include a timing module 46, which can generate and update a timing schedule of operating heating elements of the heating element layer 48 in relation to the timing of upcoming memory addresses marked for read/write operations in a memory address pipeline 39. The timing schedules of the timing module 46 can be in relation to one or more memory clock signals from control signals 42. For example, the timing module 46 can indicate that a heating element corresponding to the memory address location Adr15, should be turned on ten clock cycles from the current time. The timing module 46 can generate and update the timing schedules based on a preconfigured interval of time determined based on the specifications of the memory array 32 or alternatively, the timing schedule can be generated and updated dynamically based on data in the memory address pipeline 39. The controller 44 can be configured to turn on heating elements within the heating element layer 48 according to the timing schedule indicated by the timing module 46.

In another embodiment, the heating element layer 48 can contain additional circuitry whose rates of processing can be modulated by the controller 44. The additional circuitry could be in addition to or in lieu of microheaters. Electronic circuits produce heat as a by-product of processing data and instructions. The by-product heat that would otherwise be considered waste can be reused for the purpose of heating one or more memory cells 34 in order to temporarily reduce their voltage threshold during read/write operations.

In some embodiments, the controller 44 can send a pause signal (e.g., via chip-select signal CS of control signals 42) to halt read/write operations, while one or more memory cells 34 are heated. Alternatively, or in addition, the controller 44 can preheat one or more memory cells 34 and communicate their availability for read/write operations to one or more computing elements generating the memory address pipeline 39. For example, when a processor requests a block of memory addresses to use in upcoming processing operations, the controller 44 can communicate an address block within memory array 32, which has previously been preheated.

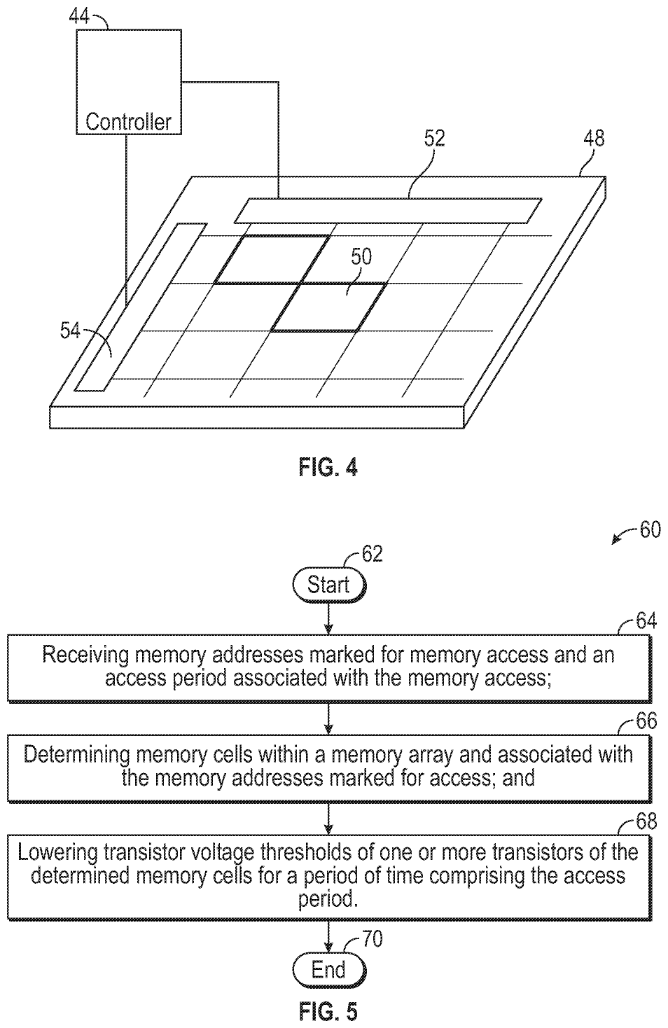

FIG. 4 illustrates a diagram of the heating element layer 48 and the controller 44 according to an embodiment. The heating element layer 48 can utilize a column, row addressing technique similar to and corresponding to the column, row technique used by memory array 32 to address and control the heating elements 50. The heating element layer 48 can additionally include column drivers 52 and row drivers 54. In another embodiment, the operations of the memory device 30 can be simplified if a cluster of heating elements 50, or a row or a column of the heating elements 50 are turned on simultaneously to heat one or more memory cells 34 in the memory array 32.

The heating elements 50 can include microheaters, which can generate heat when electrical current is run through them. A variety of materials and techniques can be used to manufacture the heating elements 50 with microheaters. For example, microheaters can be made from ceramic resistors, or from CMOS fabrication processing techniques such as laying channels in a silicon substrate with appropriate doping levels to create resistive material. In general, larger-size resistors may be used to heat several memory cells 34, while small or nanoscale resistors can be used for more targeted heating of memory cells 34. Other varieties of resistors, which can implement microheaters include printed carbon resistors, thick and thin film resistors, metal oxide film resistors, wire wound, foil resistors and others.

In one embodiment, one or more heating elements 50 can be electrically coupled to word lines, and/or bit lines used in read/write operations of the memory array 32. In this scenario, the controller 44 may be optional and the electrical currents through the word lines, and/or bit lines can turn one or more microheaters on/off during read/write operation as word lines and/or bit lines are charged and discharged for read/write operations. In another embodiment, a switch can disconnect the heating elements 50 from the read/write voltage lines after a predetermined number of cycles of read/write to avoid overheating the memory cells 34.

The heating elements 50 can include other electrical circuits whose operations can generate heat as a by-product. The by-product heat can be used to temporarily raise the temperature of one or more memory cells 34 and lower the voltage thresholds of their access transistors during read/write operations. Circuit elements whose by-product heat can be used for heating elements 50 can include transistors, processors, multi-core processors, control units, arithmetic logic units (ALUs), wire drivers, encoders, decoders, amplifiers, buffers, other memory circuits, and any type of circuits which may exist in a computing system. The circuit elements of the heating elements 50 can have an adjustable processing rate or operation rate via which by-product heat can be modulated. For example, when the circuit elements of the heating elements 50 include processors, microprocessors, multi-core processors, ALUs or other circuits which process data based on a clock signal, the clock signal can be adjusted to be made faster, thereby operating those circuits at higher clock rates and generating more by-product heat to lower the threshold voltages of one or more corresponding memory cells 34 in the memory array 32.

The controller 44 can be implemented with a variety of techniques including a field programmable gate array (FPGA) or other configurable processors and can have its own processor, memory, buffer, clock signal, and other sub-circuitry to implement its functionality. When electrical circuits are used for heating elements 50, the controller 44 can maintain a table of mapping of the heating elements 50 and memory cells 34. The table of mapping can be queried to determine the circuit elements whose processing rates can be increased to modulate transistor voltage thresholds of corresponding memory cells 34 during read/write operations.

The heating element layer 48 can be a layer in a two- or three-dimensional device, such as a three-dimensional integrated circuit. Heating element layer 48 may be manufactured as part of an integrated memory/processor system. In this scenario, the heating element layer 48 need not be a separate layer. One or more processor or processor core layers underlying or above a memory array layer can act as the heating element layer in addition to performing processing tasks.

Using the disclosed embodiments and techniques, high voltage threshold or ultra-high voltage threshold (UHVT) transistors can be used to build the memory cells 34, thereby reducing those transistor's subthreshold leakage during standby or hold time. Transistor voltage thresholds can be temporarily reduced during read and/or write operations increasing the memory device performance during read/write operations. The transistor thresholds can revert back to a high voltage threshold, thereby reducing subthreshold leakage and improving the power consumption profile a memory device utilizing the disclosed technology.

FIG. 5 illustrates a method 60 of operation of a thermally-assisted memory device according to an embodiment. The method 60 starts at the step 62. The method 60 continues to the step 64 by receiving memory addresses marked for memory access and an access period associated with the memory access. The method 60 moves to the step 66 by determining memory cells within a memory array and associated with the memory addresses marked for access. The method 60 continues to the step 68 by lowering transistor voltage thresholds of one or more transistors of the determined memory cells for a period of time comprising the access period. The method 60 ends at the step 70.

The application of the disclosed technology is not limited to the examples provided. Memory devices which utilize transistors with a temperature-dependent voltage threshold can use the described methods and systems to reduce read/write power consumption profile, while maintaining low leakage current in standby or other modes. In some embodiments, transistor voltage threshold can additionally be lowered during refresh operations or any operation where access to a memory cell is associated with increasing a voltage applied to one or more access or control transistors beyond their voltage threshold.

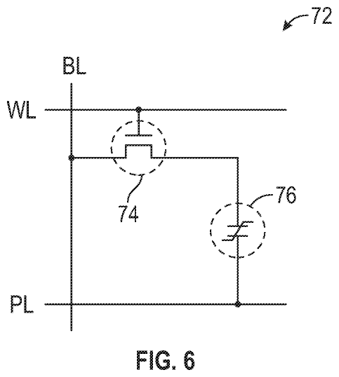

The memory cells 34 can be manufactured with ferroelectric random-access-memory (FRAM) cells, which utilize one or more access transistors. A voltage threshold of an access transistor of an FRAM cell can be modulated during access operations, in order to improve power consumption profile, while maintaining low leakage current. Various topologies for FRAM cells exist. FIG. 6 illustrates a diagram of a memory cell 72, using an example FRAM cell topology. The memory array 32 of the memory device 30 can be built using FRAM memory cells, such as memory cell 72. The operations of the memory cell 72 can be improved using the disclosed technology. The memory cell 72 includes bit line BL, word line WL, plate line PL, control transistor 74 and ferroelectric capacitor 76.

The dielectric structure of the ferroelectric capacitor 76 includes ferroelectric material, which has a nonlinear relationship between an applied electric field and the stored charge. The memory cell 72 operates similar to the memory cell 20. Writing is accomplished by applying an electric field across the ferroelectric capacitor 76 via plate line PL and control transistor 74. In reading operations, the control transistor 74 forces the memory cell 72 into a known state, for example “0” and output of the memory cell 72 is sensed. If nothing is detected, the cell held a “0”. If a temporarily discharge pulse is detected, the memory cell 72 held a “1”. As such, in some implementations, reading operations in an FRAM cell can be destructive and the FRAM cell may have to be rewritten if the stored value was changed. FRAM cells can offer a number of advantages over alternative memory structures including for example better power consumption, because the ferroelectric capacitor retains a state of charge better than a capacitor with linear dielectric structure.

Higher voltage threshold control transistors 74 can be used in the memory cell 72 to reduce steady-state leakage current. The voltage threshold of the control transistor 74 can be temporarily reduced during read/write operations by application of heat as described above. Lower voltage thresholds during read/write operations allows those operations to be performed with less power consumption, thereby efficiency of a memory device incorporating the memory cell 72 will be increased.

The timing module 46 can additionally be configured to include or determine a timing schedule of operating heating elements 50 of the heating layer 48 in relation to the type and specification of the memory cells 34 and their intended operating environments. For example, when FRAM cells are used as memory cells 34, the timing module 48 can be preloaded with timing parameters for operation heating elements 50 in a manner that avoids a long duration application of heat leading to undesirable effects, such as thermal depolarization (TD) and imprint. Various device specifications and operating conditions, such as intended operation environment, operating temperature ranges, operating voltages, currents and intended life cycle can determine the timing schedule of the timing module 46. In some embodiments, the timing module 46 can receive an environment temperature signal and generate a timing schedule of operating the heating elements 50 based at least partly on the received environment temperature signal to avoid overheating the memory cells 34.

What is claimed is:

1. A system, comprising:
a memory array comprising a plurality of memory cells, wherein memory cells comprise a plurality of transistors, each transistor having a voltage threshold;
a memory address module comprising a pipeline of memory addresses marked for access during an access period;
a heating element layer in close proximity to or adjacent to the memory array and comprising heating elements; and
a controller, in communication with the memory address module, and configured to lower one or more transistor voltage thresholds by:
determining memory cells associated with memory addresses marked for access; and
activating one or more heating elements corresponding to the determined memory cells for a period of time comprising the access period.

2. The system of claim 1, wherein the controller is further configured to send a pause signal to the memory array, pausing the access for a predetermined period of time.

3. The system of claim 1, wherein the controller comprises a timing module configured to generate and update a timing schedule of activating the one or more heating elements in relation to timing of access period.

4. The system of claim 1, wherein the heating elements comprise circuit elements having adjustable processing rates and activating the one or more heating elements comprise increasing the processing rates.

5. The system of claim 1, wherein access comprises writing into the memory cells, reading from the memory cells, or both.

6. The system of claim 1, wherein the plurality of memory cells comprise SRAM cells, DRAM cells, or FRAM cells.

7. The system of claim 1, wherein the transistors comprise high-voltage transistors or UHVT transistors.

8. The system of claim 1, wherein the heating elements comprise resistive microheaters.

9. The system of claim 1, wherein the memory cells comprise four or more transistors.

10. The system of claim 1, wherein the memory cells comprise 1T1C cells, 2T1C cells, 2T2C cells, 1T2C cells, gain cells, or a combination thereof.

11. A method comprising:
receiving memory addresses marked for memory access and an access period associated with the memory access;
determining memory cells within a memory array and associated with the memory addresses marked for access; and
lowering transistor voltage thresholds of one or more transistors of the determined memory cells for a period of time comprising the access period.

12. The method of claim 11, wherein lowering transistor voltage thresholds comprises activating one or more heating elements corresponding to the determined memory cells for a period of time comprising the access period.

13. The method of claim 12, wherein the heating elements comprise circuit elements having adjustable processing rates and activating the one or more heating elements comprise increasing the processing rates.

14. The method of claim 12, wherein the heating elements comprise resistive microheaters.

15. The method of claim 11, wherein access comprises writing into the memory cells, reading from the memory cells, or both.

16. The method of claim 11, wherein the memory cells comprise SRAM cells, DRAM cells, or FRAM cells.

17. The method of claim 11 further comprising pausing the access for a predetermined period of time.

18. The method of claim 11, wherein the memory cells comprise four or more transistors.

19. The method of claim 11, wherein the memory cells comprise 1T1C cells, 2T1C cells, 2T2C cells, 1T2C cells, gain cells, or a combination thereof.

20. A method comprising:
activating one or more heating elements, each heating element corresponding to one or more memory cells of a memory array;
determining memory addresses associated with the one or more memory cells;
receiving memory access requests from a processor, wherein the access request comprises request for writing input data into the memory array;
writing the input data into the one or more memory cells; and
deactivating the one or more heating elements.
